(19) United States
(12) Patent Application Publication
(10) Pub. No.: US 2021/0167147 A1
(43) Pub. Date: Jun. 3, 2021

(54) LIGHT EMITTING DEVICE, DISPLAY PANEL HAVING THE SAME, AND METHOD OF MANUFACTURING DISPLAY PANEL

(71) Applicant: Panasonic Intellectual Property Management Co., Ltd., Osaka (JP)

(72) Inventors: SHUHEI NAKATANI, Osaka (JP); HIDEHIRO YOSHIDA, Osaka (JP); KAZUNOBU IRIE, Hyogo (JP)

(21) Appl. No.: 17/088,699

(22) Filed: Nov. 4, 2020

(30) Foreign Application Priority Data
Nov. 29, 2019 (JP) 2019-215906

(51) Int. Cl. H01L 27/32; H01L 27/12

(52) U.S. Cl. CPC H01L 27/3246; H01L 27/3248; H01L 2227/323; H01L 27/1262; H01L 27/1218

(57) ABSTRACT

A light emitting device includes a first bank that partitions pixel regions, a second bank that is disposed above the first bank and defines the pixel regions, and a light emitting layer disposed in each of the pixel regions surrounded by the first bank or the second bank. In the light emitting device, at least one of the first bank and the second bank has a communicator via which two or more of the pixel regions including light emitting layers with a same color communicate with each other. Consequently, there are provided the light emitting device capable of improving the wettability with ink at the ends of the first bank and the second bank and thus suppressing a short circuit between an anode and a cathode and a display panel having the same.

### BACKGROUND

### 1. Technical Field

The present disclosure relates to a light emitting device, a display panel having the light emitting device, and a method of manufacturing the display panel.

### 2. Description of the Related Art

In recent years, studies for forming various electronic devices by using a printing method have been actively conducted. According to the printing method, a required amount of ink can be applied only to a required location. Therefore, compared with a vacuum vapor deposition or sputtering method of the related art, the efficiency of using a material is high. However, materials (functional materials such as light emitting materials and conductive materials) used for these electronic devices are generally very expensive. Therefore, a material loss is a major problem. On the other hand, the printing method is desirable from the viewpoint of operation energy since a film can be formed in the atmosphere.

Examples of electronic devices formed according to the printing method include wirings using conductive ink, transistors using semiconductor ink, and display devices using light emitting materials. Examples of the printing method include screen printing, letterpress printing, intaglio printing, and the like.

In recent years, an ink jet method in which there is no contact with a print target and any pattern can be formed on demand has attracted attention. Specifically, for example, development of forming a color filter, or a display device such as an organic EL display or a quantum dot display according to the ink jet method has been actively performed.

As a next-generation display, a display using an inorganic quantum dot material as a light emitting layer has been actively developed. The quantum dot is a special semiconductor with a very small diameter of 2 to 10 nanometers (10 to 50 atoms). Such a substance having the minute size expresses property different from that of a normal substance. For example, in the quantum dot, a size of a band gap can be accurately controlled by simply changing a particle size of the quantum dot. An emission wavelength of the quantum dot depends on the size of the band gap. Thus, the emission wavelength of the quantum dots can be adjusted with high accuracy by changing the particle size of the quantum dot. In other words, the emission wavelength of the quantum dots can be changed simply by changing the particle size of the quantum dots. For example, the emission wavelength of the quantum dot shifts to a blue side as the particle size of the quantum dot becomes smaller, and shifts to a red side as it becomes larger. The full width at half maximum of the emission wavelength of the quantum dot is very small. Specifically, an emission spectrum of the quantum dot is several tens of nanometers or less.

In other words, for example, when the red, blue, and green light emitting layers are formed of quantum dots, the full width at half maximum of each emission wavelength can be reduced. Thus, a light emitting layer is formed by using quantum dots, and thus a display device having high color gamut characteristics can be implemented. As a result, the performance of the display device can be considerably improved.

A typical quantum dot material includes a core made of an inorganic material such as cadmium-selenium, indium-phosphorus, copper-indium-sulfur system, silver-indium-sulfur system, and perovskite structure, and a layer called a shell made of a material such as zinc sulfide around the core. A ligand is formed around the shell to realize stability of ink.

Examples of materials of the quantum dots forming the light emitting device include a photoluminescent material that is excited by light energy to emit light, and an electroluminescent material that is excited by electric energy to emit light. For example, a quantum dot display using the photoluminescent material is used as a color filter of a micro LED display. As a quantum dot display using the electroluminescent material, there is a quantum dot display formed by thinning a quantum dot material between an anode and a cathode.

The above quantum dot display has much higher brightness and has more excellent outdoor visibility than those of an organic EL display. Thus, the quantum dot display is expected to be used in applications such as displays for mobile phones and in-vehicle devices and head mounted displays. It is expected that these displays will require a pixel resolution of 200 pixel per inch (ppi) or more in the future.

However, in a case where a display device such as a display panel is formed according to the ink jet method, it is difficult to increase a pixel resolution due to factors such as a size of a liquid droplet in ink jetting or the accuracy of a liquid droplet landing position. Thus, in forming a display device according to the ink jet method, improvement in stability of ink application to a pattern having a high pixel resolution is desired. In other words, as the pixel resolution becomes higher, a region of pixels to which ink is applied becomes smaller. Thus, in a case where the accuracy of a liquid droplet landing position in ink jetting is low, ink is printed to extrude from a pixel region. As a result, color mixing occurs between adjacent pixels.

Thus, in order to prevent color mixing with adjacent pixels, for example, International Publication No. WO2008/149498 (hereinafter, referred to as “Patent Literature 1”) discloses a method of manufacturing an organic EL device by using the ink jet method. FIG. 11 is a plan view illustrating an organic EL device disclosed in Patent Literature 1.

As illustrated in FIG. 11, the organic EL device has banks 3 that are formed in a line shape, banks 3′ that are formed to divide a region surrounded by banks 3 into two or more pixel regions 11, and functional layers such as hole transport layers 4 formed in the region surrounded by banks 3 on substrate 1. Bank 3 is made of a material that has liquid repellency to functional ink for hole transport layer 4 or the like. Red material 10R, blue material 10B, and green material 10G are disposed between banks 3.

In the structure of the organic EL device disclosed in Patent Literature 1, the wettability of the bank with ink is low. In other words, a contact angle with respect to the ink applied in the bank is high. In a state in which the contact angle is high, it becomes difficult for ink to be applied to a sidewall surface of the bank. Even though the ink is applied to the end of the bank, the surface tension of the ink may cause a decrease in a film thickness of the ink.

The organic EL device includes a functional thin film such as a light emitting layer above an anode formed in the bank, and a cathode formed above the light emitting layer. Thus, when a film thickness of the light emitting layer formed at the end of the bank is small, there is concern that the anode and the cathode may be short-circuited to each other.

### SUMMARY

The present disclosure provides a light emitting device capable of improving the wettability with ink at the end of a bank and thus suppressing a short circuit between an anode and a cathode, a display panel including the light emitting device, and a method for manufacturing the display panel.

According to the present disclosure, there is provided a light emitting device including a first bank that partitions pixel regions; a second bank that is disposed above the first bank and defines the pixel regions; and a light emitting layer that is disposed in each of the pixel regions surrounded by the first bank or the second bank. The light emitting device is configured such that at least one of the first bank and the second bank has a communicator via which two or more of the pixel regions including light emitting layers with a same color communicate with each other.

A display panel of the present disclosure includes the light emitting device.

According to the present disclosure, there is provided a method of manufacturing a display panel, including a first step of forming a first bank partitioning pixel regions including light emitting layers that emit a same light emission color among pixel regions are formed on a substrate; and a second step of forming a second bank partitioning pixel regions including light emitting layers that emit a different light emission color among the pixel regions are formed. The method of manufacturing a display panel further includes a third step of forming a light emitting layer in a region surrounded by the first bank or the second bank.

As described above, it is possible to provide a light emitting device capable of improving the wettability with ink at the end of a bank and thus suppressing a short circuit between an anode and a cathode, a display panel including the same, and a method for manufacturing the display panel.

### BRIEF DESCRIPTION OF THE DRAWINGS

FIG. 1A is a plan view of a light emitting device according to an exemplary embodiment;

FIG. 1B is a sectional view taken along line IB-IB in FIG. 1A;

FIG. 1C is a sectional view taken along line IC-IC in FIG. 1A;

FIG. 1D is a sectional view taken along line ID-ID in FIG. 1A;

FIG. 2A is a plan view of the light emitting device according to the exemplary embodiment before ink applied through ink jetting is dried;

FIG. 2B is a sectional view taken along line IIB-IIB in FIG. 2A;

FIG. 2C is a sectional view taken along line IIC-IIC in FIG. 2A;

FIG. 3 is a plan view of the light emitting device described in the same exemplary embodiment;

FIG. 4A is a plan view related to Example 1 of a light emitting device according to the exemplary embodiment;

FIG. 4B is a sectional view taken along line IVB-IVB in FIG. 4A;

FIG. 4C is a sectional view taken along line IVC-IVC in FIG. 4A;

FIG. 5A is a plan view related to Example 2 of a light emitting device according to the exemplary embodiment;

FIG. 5B is a sectional view taken along line VB-VB in FIG. 5A;

FIG. 5C is a sectional view taken along line VC-VC in FIG. 5A;

FIG. 6A is a sectional view taken along line VB-VB in FIG. 5A, illustrating an effect of the light emitting device related to Example 2;

FIG. 6B is a sectional view taken along line VB-VB in FIG. 5A, illustrating the effect of the light emitting device related to Example 2;

FIG. 6C is a sectional view taken along line VC-VC in FIG. 5A, illustrating the effect of the light emitting device related to Example 2;

FIG. 7A is a plan view related to Example 3 of a light emitting device according to the exemplary embodiment;

FIG. 7B is a sectional view taken along line VIIB-VIIB in FIG. 7A;

FIG. 8A is a plan view related to Example 4 of a light emitting device according to the exemplary embodiment;

FIG. 8B is a sectional view taken along line VIIIB-VIIIB in FIG. 8A;

FIG. 8C is a sectional view taken along line VIIIC-VIIIC in FIG. 8A;

FIG. 8D is a sectional view taken along line VIIID-VIIID in FIG. 8A;

FIG. 9A is a plan view related to Example 5 of a light emitting device according to the exemplary embodiment;

FIG. 9B is a sectional view taken along line IXB-IXB in FIG. 9A;

FIG. 9C is a sectional view taken along line IXC-IXC in FIG. 9A;

FIG. 10A is a plan view related to Example 6 of a light emitting device according to the exemplary embodiment;

FIG. 10B is a sectional view taken along line XB-XB in FIG. 10A;

FIG. 10C is a sectional view taken along line XC-XC in FIG. 10A; and

FIG. 11 is a plan view illustrating a structure of an organic EL device disclosed in Patent Literature 1.

### DETAILED DESCRIPTION

### Exemplary Embodiment

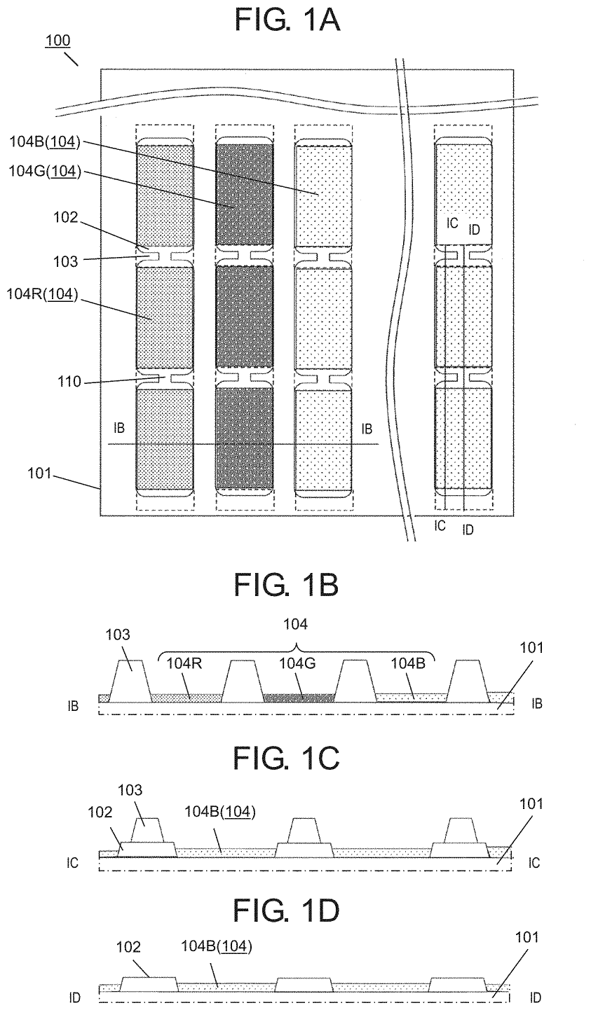

Hereinafter, light emitting device 100 according to an exemplary embodiment of the present disclosure will be described with reference to FIGS. 1A to 1D.

FIG. 1A is a plan view of light emitting device 100 according to the exemplary embodiment. FIG. 1B is a sectional view taken along line IB-IB in FIG. 1A. FIG. 1C is a sectional view taken along line IC-IC in FIG. 1A. FIG. 1D is a sectional view taken along line ID-ID in FIG. 1A.

As illustrated in FIGS. 1A to 1D, light emitting device 100 according to the present exemplary embodiment includes substrate 101, first banks 102, second banks 103, light emitting layers 104, and the like formed on substrate 101. Light emitting layers 104 include red light emitting layer 104R that emits red light, green light emitting layer 104G that emits green light, and blue light emitting layer 104B that emits blue light.

As illustrated in FIG. 1C, first banks 102 partition the same light emission color layer, for example, blue light emitting layer 104B among light emitting layers 104. As illustrated in FIG. 1C, second banks 103 communicate with each other to connect two or more pixel regions in which the same light emission color layer, for example, blue light emitting layer 104B are formed among the light emitting layers 104 via communicator 110. As illustrated in FIG. 1B, second banks 103 partition different light emission color layers, for example, red light emitting layer 104R, green light emitting layer 104G, and blue light emitting layer 104B among light emitting layers 104.

For example, a film thickness of blue light emitting layer 104B among light emitting layers 104 is smaller (thinner) than a film thickness of first bank 102, as illustrated in FIG. 1C. A film thickness of each of red light emitting layer 104R and green light emitting layer 104G is also smaller (thinner) than the film thickness of first bank 102.

Light emitting layer 104 is formed of ink in which an inorganic compound quantum dot material is dispersed in an organic solvent such as tetradecane having a relatively high boiling point. Specifically, in the ink, the content concentration of the quantum dot material contained in the ink for light emitting layer 104 is about 1% by weight to 5% by weight.

As described above, light emitting device 100 of the present exemplary embodiment is configured.

Hereinafter, steps of forming light emitting layer 104 of light emitting device 100 will be described.

First, ink in which a quantum dot material is dispersed in an organic solvent is applied on substrate 101 according to an ink jet method, and then the ink is dried. In a drying step, most of the organic solvent contained in the ink is evaporated to leave only the quantum dot material that is a solid content, and thus light emitting layer 104 is formed.

In this case, immediately after the ink for light emitting layer 104 is applied in a region surrounded by first banks 102 or second banks 103 according to the ink jet method, the ink having a liquid amount just before overflowing may be applied to each bank. In this case, when the ink just before overflowing from the bank is decompressed in a vacuum furnace to dry the organic solvent, the liquid amount of the ink decreases along a wall surface of each bank. Finally, light emitting layer 104 having a film thickness smaller than that of first bank 102, for example, a film thickness of several tens of nm is formed.

The ink also contains an additive such as a dispersant in order to disperse the quantum dot nanoparticles in an organic solvent. Thus, depending on the additive, the surface tension of the ink becomes relatively low, for example, about 15 mN/m to 25 mN/m. In other words, the ink having a low surface tension is applied to regions surrounded by first banks 102 and second banks 103. Consequently, a contact surface with each bank is easily wetted with the applied ink. Thus, it is possible to prevent the film thickness of light emitting layer 104 from being reduced on the sidewall surface of first bank 102 due to the low surface tension. In other words, there is no occurrence of a portion where ink cannot be applied on the anode or cathode electrode. As a result, it is possible to more reliably suppress the occurrence of a short circuit between anode and cathode electrodes. Here, in the present exemplary embodiment, for example, a highly reflective metal such as a silver-palladium-copper alloy is used as the anode. On the other hand, for example, a highly transparent material such as an indium tin oxide is used as the cathode.

Although not illustrated, light emitting device 100 of the present exemplary embodiment may include, in addition to light emitting layer 104, functional thin films such as a hole injection layer, a hole transport layer, and an electron injection layer (may also be referred to as functional layers). These functional thin films are designed as appropriate to have predetermined film thicknesses in consideration of light emission efficiency or light extraction efficiency of light emitting device 100. For example, light emitting device 100 is designed through microcavity design to efficiently extract emitted light. In order to design a microcavity, it is necessary to accurately adjust a film thickness of functional thin films.

The functional thin films are formed in a region defined by first banks 102. The functional thin films are formed such that a total thickness thereof is smaller than a film thickness of first bank 102. This is because, when the film thickness of the functional thin films is larger than the thickness of first bank 102, the uniformity of the film thickness of the functional thin films deteriorates in a portion beyond first bank 102. Thus, it is difficult to appropriately design the microcavity light emitting device 100.

First bank 102 is made of a resin that does not contain a liquid repellent component such as fluorine. Thus, first bank 102 is relatively easily wet with the ink that forms the functional thin films. Consequently, it is possible to form uniform functional thin films in the region defined by first banks 102.

Substrate 101 of light emitting device 100 may be transparent or opaque as described above, and may be made of any insulating material. In other words, substrate 101 may be made of, for example, glass or a flexible resin sheet such as polyimide. First bank 102 may be made of any insulating material. In other words, first bank 102 is made of, for example, a photosensitive resin such as acryl, epoxy, or polyimide, or an inorganic compound such as silicon oxide. Thus, first bank 102 has a property of being considerably wetted with ink.

On the other hand, second bank 103 may be made of any insulating material, and is made of, for example, a photosensitive resin such as acryl, epoxy, or polyimide. In the same manner as first bank 102, second bank 103 is formed on substrate 101 provided with first bank 102 according to a photolithography method using the above material.

Second banks 103 are required to store ink that forms light emitting layer 104 and the like, the ink being applied according to the ink jet method. Thus, it is desirable that second bank 103 has low wettability with ink and thus has liquid repellency. Therefore, second bank 103 is made of, for example, a resin containing a functional group having fluorine atoms. Consequently, second bank 103 having the liquid repellency to the ink is formed.

The fluororesin is not particularly limited as long as a resin has a fluorine atom in at least some recurring units among recurring units of a polymer. Examples of the fluororesin include fluorinated polyolefin resin, fluorinated polyimide resin, and fluorinated polyacrylic resin.

With the above material configuration, a static contact angle of first bank 102 with respect to the ink is 5° to 30°. On the other hand, a static contact angle of second bank 103 with respect to the ink is 30° to 70°. In other words, first bank 102 is more easily wetted with ink than second bank 103.

The thickness of first bank 102 is smaller (thinner) than the thickness of second bank 103, as described above. Specifically, the thickness of second bank 103 is approximately 0.5 μm to 3.0 μm, and is preferably 0.8 μm to 1.5 μm. On the other hand, the thickness of first bank 102 is 0.1 μm to 0.5 μm, and is preferably 0.2 μm to 0.4 μm.

Light emitting layer 104 of light emitting device 100 of the present exemplary embodiment contains the quantum dot material as described above. Specifically, the quantum dot material contained in light emitting layer 104 is made of, for example, a material having a cadmium-selenium system, an indium-phosphorus system, a copper-indium-sulfur system, a silver-indium-sulfur system, or a perovskite structure. In the ink, the above materials are dispersed by using an organic solvent as a dispersion medium. Specifically, the ink is configured such that the concentration of the quantum dot material is 0.5% by weight to 10% by weight in the dispersion medium.

As described above, the quantum dot material changes its light emission color depending on a particle size of a particle, and emits red light as the particle size becomes larger. In other words, red light emitting layer 104R, green light emitting layer 104G, and blue light emitting layer 104B are made of quantum dot materials having different particle sizes. The electron injection layer described above is formed by using, for example, ink in which nanoparticles such as zinc oxide are dispersed in an organic solvent.

Light emitting layer 104 of light emitting device 100 is configured as described above.

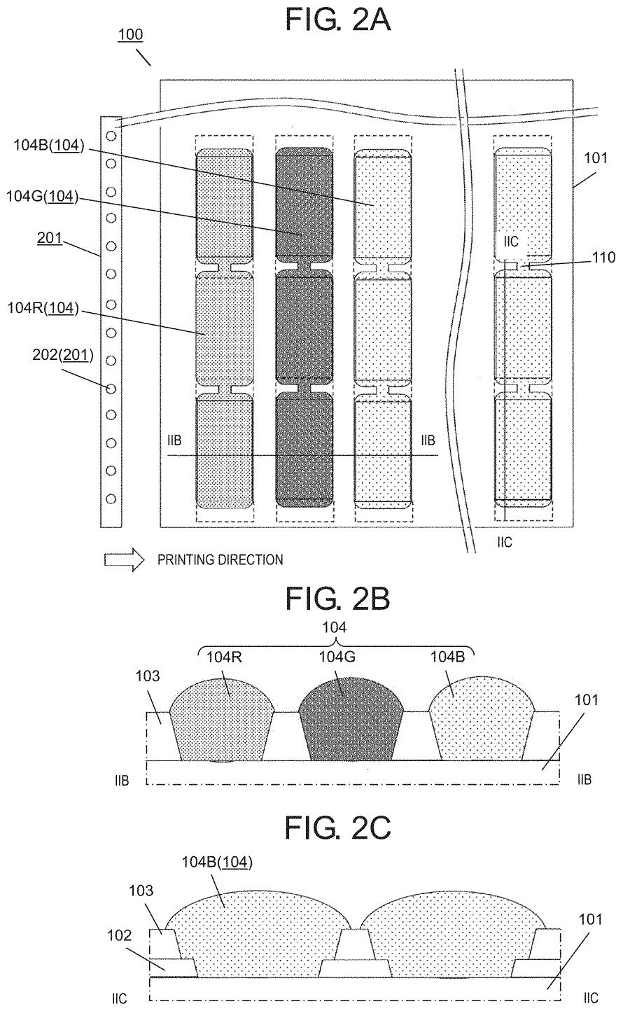

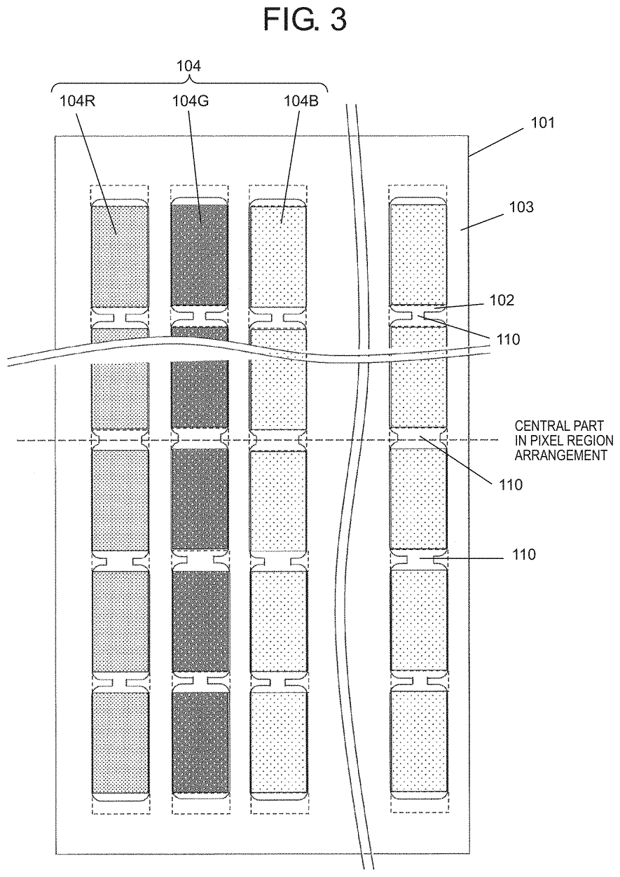

Hereinafter, a configuration of second bank 103 of light emitting device 100 of the present exemplary embodiment will be described with reference to FIGS. 2A to 3.

As described above, second banks 103 communicate with each other to connect two or more pixel regions in which light emitting layers 104 having the same light emission color are formed via communicator 110.

FIGS. 2A to 2C illustrate a state before ink is dried when the ink is applied according to the ink jet method in light emitting device 100. Specifically, FIG. 2A is a plan view of light emitting device 100. FIG. 2B is a sectional view taken along line IIB-IIB illustrated in FIG. 2A. FIG. 2C is a sectional view taken along line IIC-IIC illustrated in FIG. 2A. FIG. 3 is a plan view of light emitting device 100 after the ink is dried.

When the ink forming light emitting layer 104 is applied according to the ink jet method, liquid droplets are applied by using ink jet head 201 having plurality of nozzles 202 as illustrated in FIG. 2A. In this case, first, an amount of ink that exceeds the height of first bank 102 is applied. The ink applied to exceed the height of first bank 102 spreads in the pixel regions of light emitting layers 104 with the same color via communicator 110 of second bank 103. Through the ink application, a variation between volumes of the liquid droplets ejected from respective nozzles 202 is reduced. As a result, it is possible to uniformly apply ink to adjacent pixel regions with the same color.

Generally, a hole diameter of each nozzle 202 of ink jet head 201 varies during processing. Thus, a volume of the liquid droplets ejected from each nozzle 202 varies by a certain amount. The variation in the ejected liquid droplet causes a variation in the film thickness of light emitting layer 104. The variation in the film thickness affects the light emission characteristics of light emitting device 100. Thus, it is very important to control an amount of ink applied uniformly.

In light emitting device 100 of the exemplary embodiment, the configuration in which communicator 110 is formed only in second bank 103 has been described as an example, but is not limited thereto. For example, the communicator may be formed in either or both of first bank 102 and second bank 103. When the communicator is formed in both of the banks, it is preferable that a size of the communicator formed in second bank 103 is larger than a size of the communicator formed in first bank 102. Consequently, the applied ink flows in the communication direction with communicator 110 formed in second bank 103 as a main portion. First bank 102 has a function of electrically insulating adjacent pixels and optically blocking light emitted between the adjacent pixels. Thus, it is desirable that first bank 102 does not have the communicator.

As illustrated in FIG. 3, communicators 110 of second bank 103 are formed such that sectional areas of communicators 110 via which the pixel regions arranged on the outer side of substrate 101 communicate with each other are successively reduced from communicator 110 disposed at the central part of substrate 101 in the arrangement direction (long axis direction) of the light emitting layers 104 with the same color. In other words, communicator 110 is formed such that the sectional areas in a direction perpendicular to the communication direction are gradually reduced from the central part of substrate 101 toward the outer side thereof. Typically, when the ink applied to the region surrounded by second banks 103 is dried, a solute such as the light emitting material contained in the ink moves to the outer side due to convection. This is because, in the ink applied to the region surrounded by second banks 103, the ink located on the outer side is dried faster. Due to the movement of the ink to the outer side, the film thickness of light emitting layer 104 disposed toward the outside of the bank increases. As a result, there is concern that the film thickness of light emitting layer 104 may be non-uniform depending on a disposition location thereof.

Thus, in the present exemplary embodiment, a sectional area of the communicator is sequentially reduced to increase the flow path resistance such that the ink does not easily move toward the outside of the bank. This suppresses the outward movement of the solute in the ink during drying. As a result, it is possible to prevent the formation of a non-uniform film thickness of a light emitting layer and thus to form a light emitting layer having a more uniform film thickness.

With the device structure described above, it is possible to implement a light emitting device in which the film thickness of the light emitting layer is highly uniform by using the ink jet method. Consequently, it is possible to manufacture a display panel provided with the light emitting device having excellent light emission characteristics at low cost.

### Method of Manufacturing Light Emitting Device of Exemplary Embodiment

Hereinafter, a method of manufacturing light emitting device 100 of the present exemplary embodiment will be described with reference to FIGS. 1A to 3.

The method of manufacturing light emitting device 100 of the present exemplary embodiment includes at least three steps as described below.

The first step is a step of forming, on substrate 101, first banks 102 that partition pixel regions including light emitting layers that emit the same light emission color among the pixel regions are formed. The second step is a step of forming second banks 103 that partition pixel regions including light emitting layers including that emit different light emission colors among the pixel regions are formed. The third step is a step of applying ink containing a quantum dot material to the region surrounded by first banks 102 or second banks 103 to form light emitting layer 104.

Hereinafter, each step will be described individually.

### First Step

Hereinafter, the first step will be specifically described.

First, a photosensitive resin that is cured by exposure to ultraviolet light is applied onto substrate 101 by using an application method such as spin coating or slit coating. In this case, conditions for applying the photosensitive resin are adjusted depending on a required film thickness, such as a rotation speed in the spin coating and a scanning speed in the slit coating.

Next, a coating film of the photosensitive resin is pre-baked by using a hot plate or the like, and thus a solvent component in the photosensitive resin is evaporated such that the coating film is dried. Thereafter, the dried coating film is exposed to ultraviolet light through a photomask on which a desired pattern (corresponding to first bank 102) is formed. In this case, the photosensitive resin includes a negative type material in which an exposed portion irradiated with ultraviolet light is cured and a positive type material in which an unexposed portion to ultraviolet light is cured.

Thus, next, an uncured portion of the photosensitive resin is removed by using an appropriate developing solution according to the type of photosensitive resin material to be used.

Next, the photosensitive resin pattern remaining after the removal is post-baked in a curing furnace or the like.

First banks 102 are formed through the above first step.

### Second Step

Next, the second step will be specifically described.

The second step is a step of forming second bank 103 on the outer side (outer periphery) of first bank 102.

Specifically, similarly to first bank 102, second bank 103 is formed through a photolithography process by using a photosensitive resin. In this case, a film thickness of second bank 103 is formed to be larger than a film thickness of first bank 102 (including a film thickness to the same degree).

In the above description, a description has been made of an example in which first bank 102 is formed in the first step and second bank 103 is formed in the second step, that is, the first bank and the second bank are formed in different steps, but the present disclosure is not limited thereto. First bank 102 and second bank 103 may be formed simultaneously in a single step, for example.

Specifically, the transmittance of, for example, a photomask with respect to ultraviolet light is locally changed, and the photosensitive resin applied to substrate 101 is half-etched. Consequently, patterns of first bank 102 and second bank 103 having different film thicknesses can be simultaneously formed.

For example, in a case where a photosensitive resin of a negative type material is used, an amount of transmitted ultraviolet light is reduced in a portion of which a film thickness is desired to be small. Consequently, since the degree of curing is reduced in a portion where an exposure amount is small, a large amount of the photosensitive resin is etched by a developing solution.

Through the above method, first bank 102 and second bank 103 having different film thicknesses can be simultaneously formed in a single step. As a result, productivity can be improved.

### Third Step

Next, the third step will be specifically described.

First, ink in which a quantum dot material is dispersed in a solvent at a predetermined concentration is applied to the region surrounded by second banks 103 according to an ink jet method. In this case, an amount of the ejected ink from nozzle 202 of ink jet head 201 is determined such that a film thickness of the applied ink after drying is a predetermined film thickness.

Next, the ink applied on substrate 101 is dried under reduced pressure in a drying furnace. Specifically, the internal pressure of the drying furnace is reduced by a vacuum pump such that the ink is dried. As a result, the evaporation of the solvent in the ink is promoted, and the ink is dried. Typically, in the ink ejected from ink jet head 201, a solvent having a high boiling point is often used in order to suppress drying of the solvent when the ink is held in nozzle 202. Thus, the solvent in the ink is hardly dried. Therefore, decompression drying is used when the coating film is dried. Consequently, the solvent having a high boiling point contained in the ink of the coating film can be efficiently evaporated.

Conditions for the decompression drying are, for example, an ultimate vacuum degree of several Pa and a holding time of several tens of minutes. However, the ultimate vacuum degree and holding time conditions differ depending on the boiling point of the solvent contained in the ink. Thus, the above-described decompression drying conditions are only examples, and the present disclosure is not limited to the conditions.

In a case of ink in which a quantum dot material is dispersed only in an ultraviolet curable resin instead of a solvent being contained in the ejected ink, the solvent may not be dried through decompression drying.

Next, substrate 101 on which a coating film of the ink dried under reduced pressure is formed is placed on, for example, a hot plate. The coating film is pre-baked by the hot plate under conditions of, for example, 100° C. and 5 minutes.

Next, the pre-baked coating film is irradiated with ultraviolet light having a wavelength of 365 nm, and thus the coating film is exposed and cured. In this case, an irradiation amount of the ultraviolet light is, for example, 200 mJ/cm² to 1000 mJ/cm².

Next, the coating film that has been exposed to and cured by the ultraviolet light is post-baked in a curing furnace under the conditions of, for example, 150° C. and about 20 minutes. Consequently, light emitting layer 104 is formed.

As described above, light emitting device 100 of the present exemplary embodiment is manufactured.

### Example 1

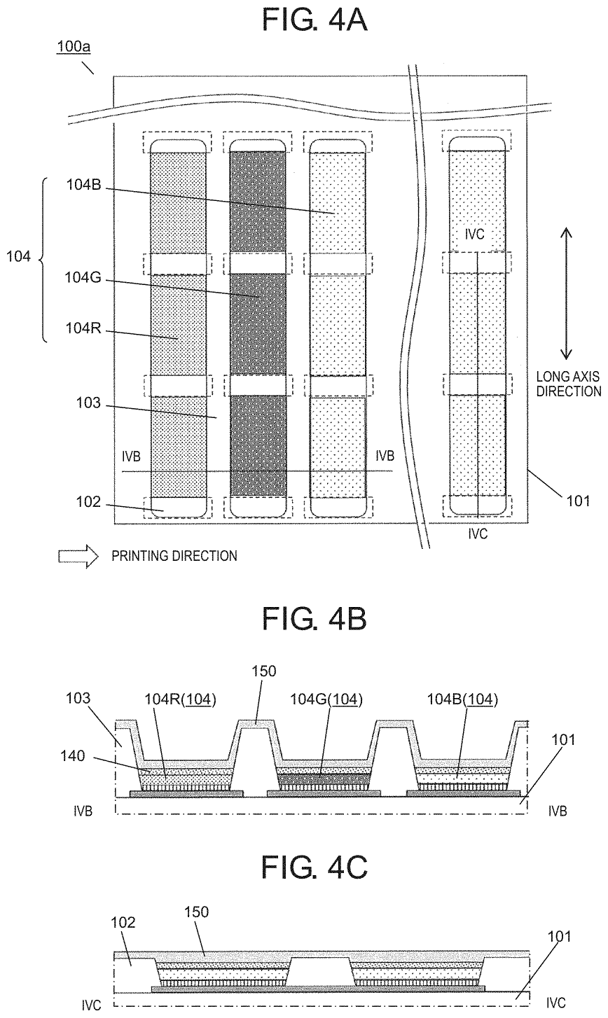

Hereinafter, light emitting device 100a related to Example 1 of light emitting device 100 of the present exemplary embodiment will be described with reference to FIGS. 4A to 4C.

FIG. 4A is a plan view of light emitting device 100a related to Example 1. FIG. 4B is a sectional view taken along line IVB-IVB in FIG. 4A. FIG. 4C is a sectional view taken along line IVC-IVC in FIG. 4A.

As illustrated in FIGS. 4A to 4C, light emitting device 100a related to Example 1 includes reflective anode 120 formed on substrate 101 such as glass.

Hereinafter, a method for manufacturing light emitting device 100a will be described.

First, reflective anode 120 is formed on substrate 101. Specifically, for example, a silver-palladium-copper alloy having a high reflectance is formed on substrate 101 according to a sputtering method. Thereafter, reflective anode 120 is formed through patterning in accordance with a pixel region by using a photolithography method.

Next, first banks 102 are formed to partition light emitting layers 104 with the same color. Here, light emitting layers 104 with the same color include red light emitting layer 104R that emits red light, green light emitting layer 104G that emits green light, and blue light emitting layer 104B that emits blue light. In this case, it is desirable that first banks 102 are formed of a photosensitive resin such as an acrylic resin that is easily wetted with ink forming a film such as light emitting layer 104 in first bank 102 and does not contain a liquid repellent component such as fluorine. In other words, first banks 102 are formed by patterning the above material according to a photolithography method.

Specifically, first, the acrylic resin is applied onto substrate 101 through slit coating, and is pre-baked at 80° C. for 30 minutes on a hot plate. Thereafter, the acrylic resin is cured by applying ultraviolet light having a wavelength of 365 nm. In this case, an exposure amount is 500 mJ/cm².

Next, the acrylic resin cured by the ultraviolet light is developed. The development is performed through spray coating for 60 seconds by using, for example, a developing solution such as Na₂CO₃ of 1% by weight.

Next, the developed acrylic resin is post-baked at 150° C. for 60 minutes by using a heating furnace.

Next, second banks 103 are formed to partition pixel regions with different light emission colors. Second banks 103 are linearly formed to include two or more pixel regions in which the light emitting layers with the same color partitioned by first banks 102 are formed. In this case, second bank 103 is formed by using a fluorine-containing acrylic resin containing fluorine.

Specifically, second bank 103 is formed according to the photolithography method in the same manner as first bank 102. In this case, a material having a feature that fluorine is unevenly distributed on a surface thereof through exposure is used as the fluorine-containing acrylic resin. Consequently, second bank 103 having a lyophilic side surface and a lyophobic top is formed. In this case, a static contact angle of second bank 103 with respect to the ink is about 50°. A film thickness of first bank 102 is 0.3 μm, and a film thickness of second bank 103 is 1.0 μm.

Next, hole injection layer 130 is formed on reflective anode 120 in a pixel region formed by first bank 102 and second bank 103. Ink forming hole injection layer 130 is formed by dissolving 2.0% by weight of a solid content such as polyethylenedioxythiophene/polystyrenesulfonic acid (PEDOT/PSS) in an alcohol solvent. The ink formed as described above is applied to the pixel region according to an ink jet method. In this case, the ink is applied from the nozzle in an ejection amount such that a film thickness of the solvent contained in the ink after drying is 50 nm. The solvent is dried through vacuum drying in which a furnace is depressurized with a vacuum pump. The vacuum drying is performed, for example, at the vacuum degree of several Pa for a holding time of 15 minutes.

Next, red light emitting layer 104R, green light emitting layer 104G, and blue light emitting layer 104B forming light emitting layers 104 are formed on hole injection layer 130. Specifically, as the ink forming light emitting layer 104, ink in which a cadmium-selenium-based quantum dot material is dispersed in a linear aliphatic organic solvent in a concentration of 2.5% by weight is used. A quantum dot material having a particle size of 10 to 30 nm is used. The ink is applied to the region surrounded by second banks 103 according to an ink jet method. In this case, the ink is applied to cover first banks 102. Thus, when the applied ink is wet, first bank 102 is also coated with the ink. In other words, in the formation of light emitting layer 104, in order to apply the ink in the above-described form, it is desirable that first bank 102 has a contact angle as low as possible and is easily wetted with the ink, and is further lyophilic.

As illustrated in FIG. 4A, the ink is printed in a direction perpendicular to the long axis direction of second bank 103 in which the pixels of red light emitting layer 104R, green light emitting layer 104G, and blue light emitting layer 104B are arranged. In other words, nozzles 202 of ink jet head 201 are provided to be arranged in a direction in which pixels including light emitting layers 104 with the same light emission color are arranged. Thus, regarding an ink landing position during ejection, the ink can be relatively easily landed at a predetermined position by adjusting an ejection timing in the printing direction.

However, it is hard to correct an ink landing position in the arrangement direction of nozzles 202 (long axis direction), and, thus, as described above, the ink landing position depends on the processing accuracy (in particular, a hole diameter) of nozzle 202. Therefore, a region where ink can be landed is widened in the arrangement direction of the nozzles 202. Consequently, it is possible to increase an allowed fluctuation range of an ink landing position.

A plurality of nozzles 202 are disposed in the ink application region. Consequently, even though a certain nozzle 202 cannot eject ink due to clogging of foreign substances or the like, it is possible to supplement the ink with ink ejected from the adjacent nozzle 202.

A pixel region including two or more light emitting layers 104 with the same color is defined by second banks 103. Thus, ink forming light emitting layer 104 such as red light emitting layer 104R can be applied within second banks 103 by using plurality of nozzles 202. Consequently, it is possible to average variations in volumes of liquid droplets of ink ejected from nozzles 202 of ink jet head 201.

Next, the solvent in the ink forming light emitting layers 104 is dried through vacuum drying. In this case, the vacuum drying was performed under the conditions that the vacuum degree was several Pa and the drying time was 20 minutes. Consequently, the solvent in the ink is dried after vacuum drying, and a film thickness of the ink becomes smaller than that of first bank 102. Thus, the ink covering first bank 102 also disappears immediately after the above-described application.

Next, electron injection layer 140 is formed after light emitting layers 104 are formed. For example, ink in which zinc oxide nanoparticles are dispersed in an alcohol-based organic solvent is used to form electron injection layer 140. The nanoparticles dispersed in the organic solvent have a particle size of 5 nm to 20 nm, and the concentration of nanoparticles in the ink is 3.0% by weight. The ink formed in the above-described way is applied onto red light emitting layer 104R, green light emitting layer 104G, and blue light emitting layer 104B according to an ink jet method.

Next, after the ink is applied, the ink is dried through vacuum drying such that the solvent in the ink is dried in the same manner as in hole injection layer 130 and light emitting layer 104.

Finally, as illustrated in FIGS. 4B and 4C, transparent electrode 150 made of, for example, indium tin oxide is formed on the entire surface of substrate 101 on which the functional films (functional layers) are formed.

In this case, it is desirable that second bank 103 is formed in a shape with a smoothly rounded corner or a shape with a low taper angle. Consequently, the coverage of transparent electrode 150 on second bank 103 can be improved.

In the present exemplary embodiment, the microcavity design improves the light emission characteristics of the light emitting device by utilizing the microcavity effect of efficiently extracting light emitted from light emitting layer 104 to the outside. Here, the microcavity effect is an effect of enhancing a light emission color by adjusting a film thickness of light emitting layer 104, hole injection layer 130, or the like to resonate and emphasize light with a specific wavelength.

The above-described microcavity design is performed by controlling film thicknesses of functional films such as hole injection layer 130, light emitting layer 104, and electron injection layer 140, and thus the uniformity of these film thicknesses is considerably important. Thus, in the microcavity design, a total thickness of laminated films of these functional layers is preferably smaller than a thickness of first bank 102. This is because, when these laminated films are formed to exceed the thickness of first bank 102, a film shape becomes non-uniform in the exceeded portion. As a result, it is difficult to control film thicknesses of these laminated films.

Light emitting device 100a having the structure and manufactured according to the manufacturing method and the display panel including the same have high film thickness uniformity. Consequently, it is possible to implement a display panel having excellent light emission characteristics.

### Example 2

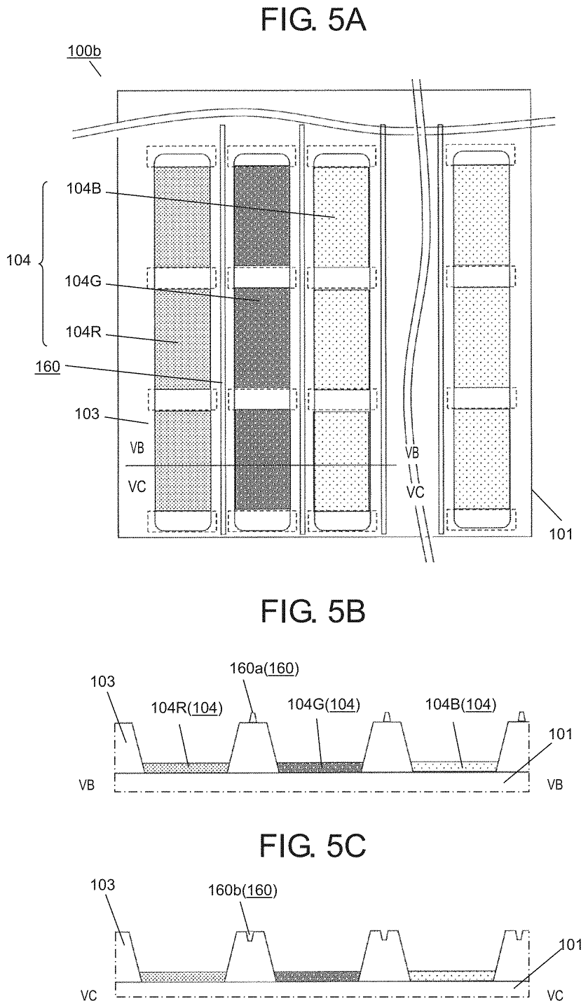

Hereinafter, light emitting device 100b related to Example 2 of light emitting device 100 of the present exemplary embodiment will be described with reference to FIGS. 5A to 5C.

FIG. 5A is a plan view of light emitting device 100b related to Example 2. FIGS. 5B and 5C are respectively sectional views taken along lines VB-VB and VC-VC in FIG. 5A.

As illustrated in FIGS. 5A to 5C, a structure of light emitting device 100b related to Example 2 is different from the structure of light emitting device 100a of Example 1 in that unevenness 160 including one of a protrusion step and a depression step is formed on second banks 103 that partition the pixel regions with different light emission colors.

In this case, unevenness 160 is formed in a stepped shape and includes protrusion step 160a illustrated in FIG. 5B or depression step 160b illustrated in FIG. 5C. A height of protrusion step 160a or a depth of depression step 160b is, for example, about 100 nm to 200 nm.

Protrusion step 160a and depression step 160b are formed according to a photolithography method by using, for example, photomasks having different transmittances.

As described above, ink in which the nanoparticles such as a quantum dot material are dispersed is added with a dispersant such as a surfactant for dispersing the nanoparticles, or various additives for improving the dispersion stability. A bank may have high wettability with such ink. Specifically, ink forming red light emitting layer 104R, green light emitting layer 104G, and blue light emitting layer 104B using the quantum dot material has 5° to 20° as a receding contact angle with respect to second bank 103. In contrast, ink in which a polymer is dissolved, for example, ink forming a light emitting layer of organic EL has about 25° to 40° as a receding contact angle. In other words, the receding contact angle of the ink in which the nanoparticles are dispersed is lower than the receding contact angle of the ink in which the polymer is dissolved. However, in a case where the receding contact angle is low, for example, when ink for red light emitting layer 104R is applied to a region surrounded by second banks 103 and then a solvent that is a dispersion medium is dried, the ink may remain on the top of second bank 103. Depending on the type of ink, the dispersion medium may be a photosensitive resin. In the case of this ink, after the ink is exposed to light to be cured and contracted, the ink may remain on the top of second bank 103.

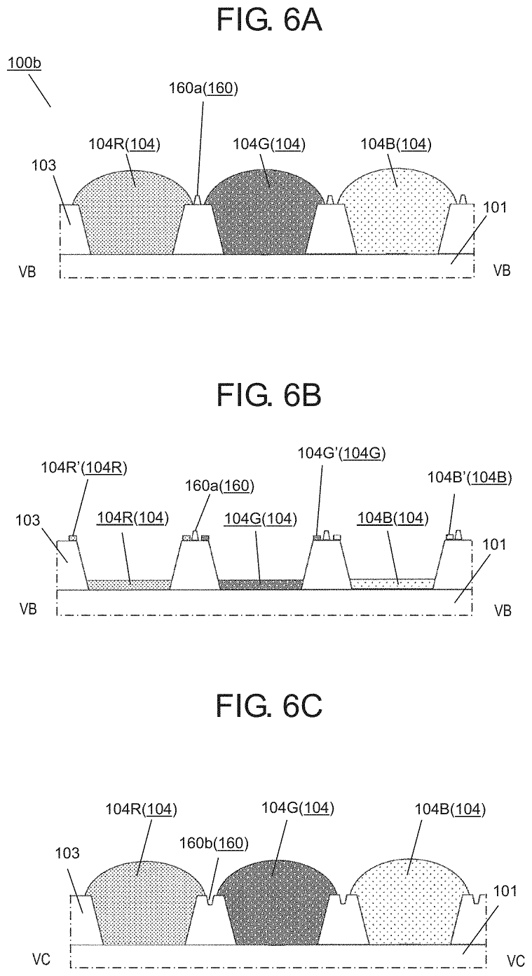

Hereinafter, with reference to FIGS. 6A to 6C, a description will be made of a residue of ink after the ink is applied and dried.

FIG. 6A is a sectional view illustrating a state before ink is dried immediately after ink for red light emitting layer 104R, ink for green light emitting layer 104G, and ink for blue light emitting layer 104B are applied to regions surrounded by second banks 103 in light emitting device 100b of Example 2. FIG. 6B is a sectional view illustrating a state after the ink illustrated in FIG. 6A is dried.

As illustrated in FIG. 6A, the applied ink is applied separately by using protrusion step 160a disposed on second bank 103 as a boundary.

When the applied ink is dried through vacuum drying, the state illustrated in FIG. 6B is obtained. In this case, since the receding contact angle of the ink is low, residues of the ink are present on second bank 103 as illustrated in FIG. 6B. Specifically, the residues include residue 104R′ of the ink for red light emitting layer 104R, residue 104G′ of the ink for green light emitting layer 104G, and residue 104B′ of the ink for blue light emitting layer 104B.

In a case where the ink remains on the top of second bank 103, when ink with a different color is applied, for example, when the ink for green light emitting layer 104G is applied to the pixel region adjacent to red light emitting layer 104R, color mixing may occur due to the remaining ink on second bank 103. In other words, for example, in FIG. 6, in a case where red ink is applied and then green ink is applied to the adjacent pixel region, when there is the residue of the red ink on second bank 103, wettability increases in a wet residue of the ink. Thus, when the green ink is applied, the repellency (liquid repellency) to the green ink becomes weak, and thus the green ink may flow into the red pixel region to cause color mixing.

Therefore, in light emitting device 100b of Example 2, stepped unevenness 160 is provided on second bank 103. Consequently, in adjacent pixel regions, color mixing due to ink for light emitting layers with different colors can be suppressed more reliably.

As illustrated in FIG. 6C, when the depression step 160b is provided on second bank 103, ink applied on second bank 103 stops spreading at the edge of depression step 160b due to surface tension. Thus, it is possible to prevent color mixing of ink in adjacent pixel regions.

As described above, with the structure of light emitting device 100b of Example 2, it is possible to apply ink in which the quantum dot material having high film thickness uniformity and high wettability is dispersed without causing color mixing. Consequently, it is possible to provide a display panel having excellent light emission characteristics.

In light emitting device 100b of Example 2, although not particularly illustrated in order to describe the effect, when a display panel is manufactured by using light emitting device 100b, in the same manner as in Example 1, needless to say, a reflective anode, a hole injection layer, an electron injection layer, a transparent electrode, and the like are formed.

### Example 3

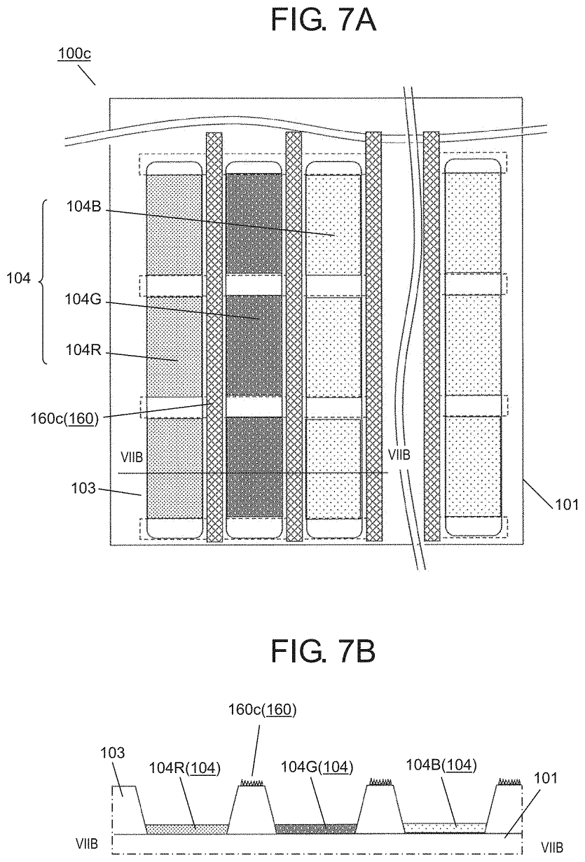

Hereinafter, light emitting device 100c related to Example 3 of light emitting device 100 of the present exemplary embodiment will be described with reference to FIGS. 7A and 7B.

FIG. 7A is a plan view of light emitting device 100c related to Example 3. FIG. 7B is a sectional view taken along line VIIB-VIIB in FIG. 7A.

As illustrated in FIGS. 7A and 7B, light emitting device 100c related to Example 3 is different from light emitting device 100b related to Example 2 in that fine uneven structure 160c is provided on the top of second bank 103.

Uneven structure 160c has a height in the order of nanometers, specifically, a height of several nanometers to several tens of nanometers. By forming uneven structure 160c with such a surface shape, a phenomenon called super water repellency appears between a liquid and a solid. Consequently, a contact angle of the liquid is increased.

In other words, in a configuration of the related art, the receding contact angle can be increased even with ink having a low receding contact angle on second bank 103. Consequently, it is possible to suppress a residue of the ink on second bank 103 and thus to more reliably prevent color mixing between different colors applied to adjacent pixel regions.

### Example 4

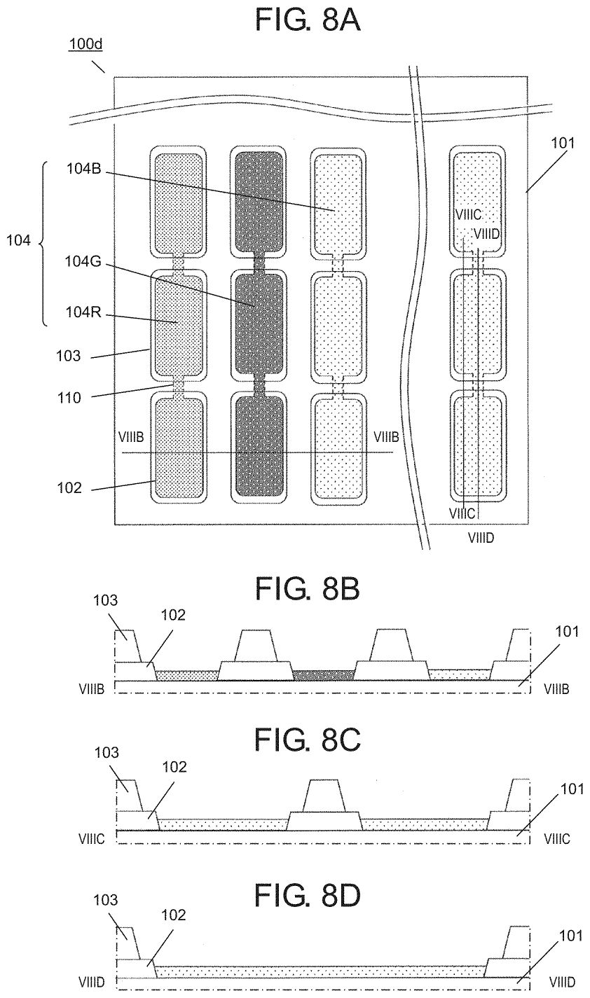

Hereinafter, light emitting device 100d related to Example 4 of light emitting device 100 of the present exemplary embodiment will be described with reference to FIGS. 8A to 8D.

FIG. 8A is a plan view of light emitting device 100d related to Example 4. FIG. 8B is a sectional view taken along line VIIIB-VIIIB in FIG. 8A. FIG. 8C is a sectional view taken along line VIIIC-VIIIC in FIG. 8A. FIG. 8D is a sectional view taken along line VIIID-VIIID in FIG. 8A.

As illustrated in FIGS. 8A to 8D, light emitting device 100d related to Example 4 is different from light emitting device 100a related to Example 1 in that first banks 102 communicate with each other to connect two or more pixel regions of light emitting layers with the same color via communicator 110. Light emitting device 100d related to Example 4 is different from light emitting device 100a related to Example 1 in that second banks 103 are formed to partition pixel regions of light emitting layers with the same color and pixel regions of light emitting layers with different colors. In other words, the pixel regions of the light emitting layers with the same color are not connected to each other via second bank 103, and the pixel regions of the light emitting layers with different colors are not connected with each other via second bank 103 either.

With the configuration of light emitting device 100d, ink applied according to an ink jet method spreads in pixel regions of light emitting layers with the same color via only communicator 110 of first bank 102. Consequently, it is possible to improve the film thickness uniformity of light emitting layers in the same manner as in Example 1.

### Example 5

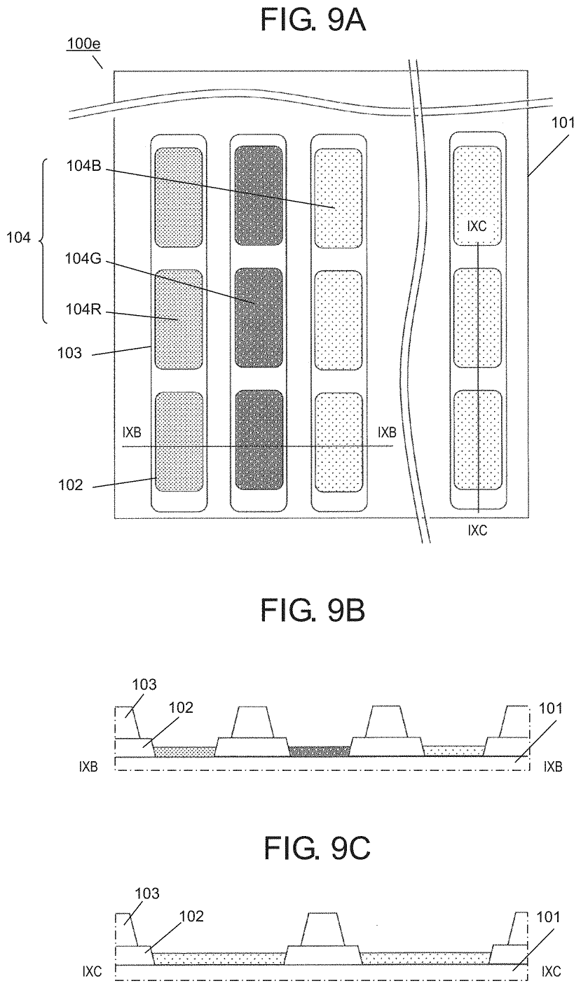

Hereinafter, light emitting device 100e related to Example 5 of light emitting device 100 of the present exemplary embodiment will be described with reference to FIGS. 9A to 9C.

FIG. 9A is a plan view of light emitting device 100e related to Example 5. FIG. 9B is a sectional view taken along line IXB-IXB in FIG. 9A. FIG. 9C is a sectional view taken along line IXC-IXC in FIG. 9A.

As illustrated in FIGS. 9A to 9C, light emitting device 100e related to Example 5 is different from light emitting device 100a related to Example 1 in that first banks 102 are disposed in not only a direction in which pixel regions of light emitting layers with the same color are arranged but also a direction in which pixel regions of light emitting layers with different colors are arranged.

With the configuration of light emitting device 100e, the entire circumference of each light emitting region of light emitting layers with the same color and different colors is surrounded by first banks 102. Consequently, it is possible to improve the film thickness uniformity of light emitting layers in the same manner as in Example 1.

### Example 6

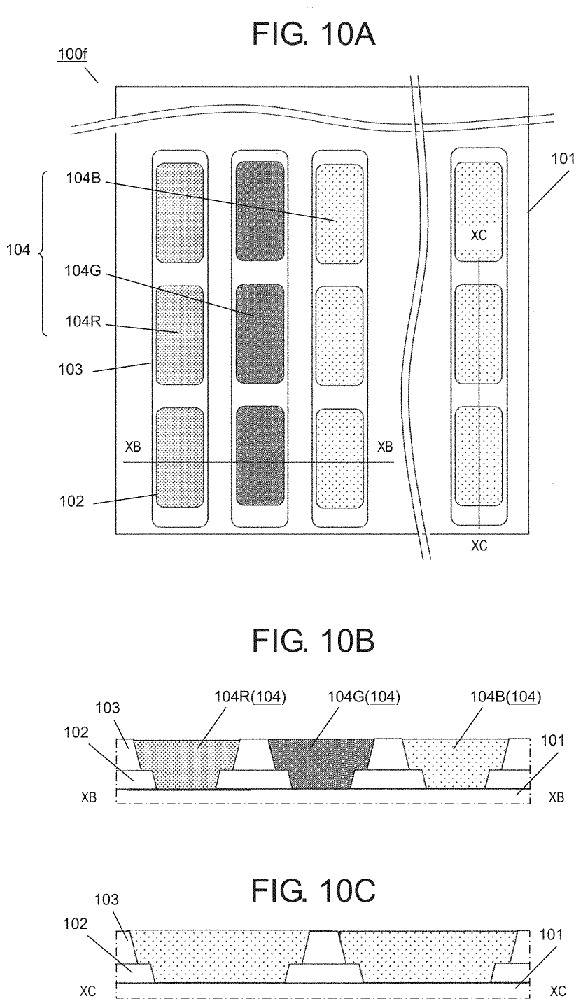

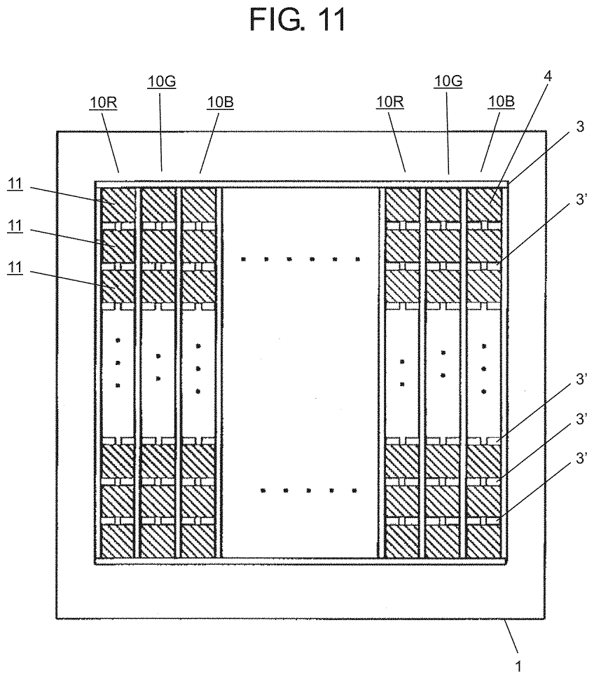

Hereinafter, light emitting device 100f related to Example 6 of light emitting device 100 of the present exemplary embodiment will be described with reference to FIGS. 10A to 10C.

FIG. 10A is a plan view of light emitting device 100f related to Example 6. FIG. 10B is a sectional view taken along line XB-XB in FIG. 10A. FIG. 10C is a sectional view taken along line XC-XC in FIG. 10A.

As illustrated in FIGS. 10A to 10C, light emitting device 100f related to Example 6 is different from light emitting device 100e of Example 5 that is made of a light emitting material that emits light through photoexcitation in that red light emitting layer 104R, green light emitting layer 104G, and blue light emitting layer 104B are made of a material that emits light through electric field excitation.

In the case of a light emitting material that emits light through photoexcitation, light emitting layer 104 is formed to have a film thickness of about 5 μm to 10 μm. The reason is that, in a case of a light emitting device using a photoexcitation material, a blue LED may be used as a photoexcitation light source. However, the efficiency of converting blue as a light emission color into red or green is low. Therefore, light emitting layer 104 is made thicker such that the light emission efficiency is ensured.

A composition of ink forming light emitting layer 104 is a photosensitive acrylic resin or an epoxy resin that is cured by light instead of that of ink in which quantum dots are dispersed in an organic solvent as in Examples 1 to 4. In this case, the ink contains not only a light emitting material such as the quantum dots but also a scattering agent having a light scattering effect. Specifically, the scattering agent is, for example, particles of titanium oxide.

Light emitting device 100f made of the above material functions as a color conversion device. Thus, light emitting device 100f can be used as, for example, a color filter of a micro LED display.

In this case, light emitting device 100f is used by being bonded to a substrate on which blue LEDs are arranged. Consequently, it is possible to improve the film thickness uniformity of light emitting layers in the same manner as in Examples 1 to 5.

1. A light emitting device comprising:
a first bank that partitions pixel regions;
a second bank that is disposed above the first bank and defines the pixel regions; and
a light emitting layer that is disposed in each of the pixel regions surrounded by the first bank or the second bank,
wherein at least one of the first bank and the second bank has a communicator via which two or more of the pixel regions including light emitting layers with a same color communicate with each other.

2. The light emitting device of claim 1,
wherein a wettability of the first bank with respect to ink forming the light emitting layer is higher than a wettability of the second bank with respect to the ink.

3. The light emitting device of claim 1,
wherein a thickness of the first bank is smaller than a thickness of the second bank.

4. The light emitting device of claim 1,
wherein a size of the communicator of the first bank is smaller than a size of the communicator of the second bank.

5. The light emitting device of claim 1,
wherein the communicator has a sectional area perpendicular to a direction of the communication, the sectional area decreasing as the communicator is farther from a center of an arrangement of the two or more of pixel regions having the light emitting layers with the same color.

6. The light emitting device of claim 1,
wherein a thickness of the first bank is larger than a total thickness of a plurality of functional layers disposed in the pixel region, including the light emitting layer.

7. The light emitting device of claim 1,
wherein a static contact angle of a top of the first bank with respect to ink for the light emitting layer is 5 degrees to 30 degrees, and a static contact angle of the second bank with respect to the ink is 30 degrees to 70 degrees.

8. The light emitting device of claim 1,
wherein the light emitting layer is made of an inorganic quantum dot material.

9. The light emitting device of claim 8,
wherein a receding contact angle of a top of the second bank with respect to ink for the light emitting layer is 5 degrees to 15 degrees.

10. The light emitting device of claim 1,
wherein the second bank that partitions pixel regions that emit different light emission colors among the pixel regions is formed in two or more stepped shapes in parallel to a direction in which pixel regions that emit same light emission colors among the pixel regions are arranged.

11. The light emitting device of claim 1,
wherein the top of the second bank has an uneven surface.

12. A display panel comprising the light emitting device of claim 1.

13. A method of manufacturing a display panel, comprising:
forming a first bank partitioning pixel regions including light emitting layers that emit same light emission colors among pixel regions are formed on a substrate;
forming a second bank partitioning pixel regions including light emitting layers that emit different light emission colors among the pixel regions are formed; and
forming a light emitting layer in a region surrounded by the first bank or the second bank.
